(19) United States
(12) Patent Application Publication
(10) Pub. No.: US 2010/0019324 A1
(43) Pub. Date: Jan. 28, 2010

(54) MANUFACTURING METHOD OF SEMICONDUCTOR DEVICE AND SEMICONDUCTOR DEVICE

(76) Inventors: Hiroyuki Ohara, Tokyo (JP); Shino Takahashi, Tokyo (JP); Kenji Kanamitsu, Tokyo (JP); Shuji Matsuo, Tokyo (JP)

Correspondence Address: MILES & STOCKBRIDGE PC, 1751 PINNACLE DRIVE, SUITE 500, MCLEAN, VA, 22102-3833, US

(21) Appl. No.: 12/519,489

(22) PCT Filed: Dec. 22, 2006
(86) PCT No.: PCT/JP2006/325633

§ 371 Date: Jun. 16, 2009

(51) Int. Cl. H01L 27/092; H01L 21/336; H01L 21/8238

(52) U.S. Cl. 257/369; 438/303; 438/231; 257/E27.062; 257/E21.634; 257/E21.409

(57) ABSTRACT

By ion-implanting an inert gas, for example, nitrogen into a polycrystalline silicon film in an nMIS forming region from an upper surface of the polycrystalline silicon film down to a predetermined depth, an upper portion of the polycrystalline silicon film is converted to an amorphous form to form an amorphous/polycrystalline silicon film. And then, an n-type impurity, for example, phosphorous is ion-implanted into the amorphous/polycrystalline silicon film to form an n-type amorphous/polycrystalline silicon film, the n-type amorphous/polycrystalline silicon film is processed to form a gate electrode having a gate length shorter than 0.1 μm, a sidewall formed of an insulating film is formed on a side wall of the gate electrode, and a source/drain diffusion layer is formed. Thereafter, a cobalt silicide (CoSi₂) layer is formed on an upper portion of the gate electrode by salicide technique.

### TECHNICAL FIELD

The present invention relates to a manufacturing technique of a semiconductor device and a semiconductor device, and more particularly to a technique effectively applied to a manufacture of a field-effect transistor.

### BACKGROUND ART

Japanese Patent Application Laid-Open Publication No. 2004-172389 (refer to Patent Document 1) discloses a technique in which an ion being electrically inactive and having a relatively large mass number (mass number of 70 or larger), for example, Ge ion is ion-implanted into a gate electrode of, for example, an nMOS transistor followed by performing a thermal process of about 950 to 1100° C. thereto so that a strong pressure stress remains inside the gate electrode to apply a tensile stress to a channel region below the gate electrode, thereby improving a carrier mobility of the nMOS transistor.

In addition, Japanese Patent Application Laid-Open Publication No. 2003-78027 (refer to Patent Document 2) discloses a technique in which an inert gas, for example, Ar or N₂ is angle-implanted onto a semiconductor substrate having a gate pattern formed of a conductive layer and a metal layer followed by performing a thermal process at a low temperature so that only the conductive layer is selectively oxidized, thereby compensating a side wall of the conductive layer, and also forming a metal nitride layer on a surface of the metal layer.

Also, Japanese Patent Application Laid-Open Publication No. 2003-68670 (refer to Patent Document 3) discloses a technique in which a thermal process is introduced before forming a titanium film for a silicide formation to roughen a surface of a gate electrode and a source/drain region so that a crystal nucleus is increased to easily cause a phase transition of the formed titanium film, thereby obtaining a low-resistance titanium silicide layer.
Patent Document 1: Japanese Patent Application Laid-Open Publication No. 2004-172389 (paragraph [0043] to [0045], FIG. 12)
Patent Document 2: Japanese Patent Application Laid-Open Publication No. 2003-78027 (paragraph [0058] to [0061], FIG. 5)
Patent Document 3: Japanese Patent Application Laid-Open Publication No. 2003-68670 (paragraph [0032] to [0038], FIG. 8)

### DISCLOSURE OF THE INVENTION

### Problems to be Solved by the Invention

As promoting a high integration of a semiconductor device, a field-effect transistor is microfabricated in accordance with a scaling rule, but there arises a problem that resistances of a gate and a source/drain are increased and high-speed operation cannot be obtained even if the field-effect transistor is microfabricated. Accordingly, in a field-effect transistor having a gate length of, for example, 0.2 μm or shorter, the salicide technique has been studied, in which a silicide layer with low resistance, for example, a cobalt silicide layer, a nickel silicide layer, or the like is formed in a self-alignment manner on a surface of a conductive film configuring a gate and a surface of a semiconductor region configuring the source/drain, thereby reducing the resistance of the gate and the source/drain to 10 Ω/sq. or lower.

However, there are various technical issues described below in a field-effect transistor having a gate length of 0.1 μm or shorter.

Currently, a single bit defect caused in a memory unit is taken as one of main causes of reducing a manufacturing yield in SRAM (Static Random Access Memory) adopting a field-effect transistor having a gate length of 0.085 μm. Since the single bit defect is caused mostly at a disconnecting portion of a silicide layer formed on an upper portion of a gate, it is considered that the single bit defect is caused by high resistance of the gate due to the disconnection of the silicide layer. That is, for example, while a resistance of a cobalt silicide layer is 6 to 8 Ω/sq., a resistance of a conductive film made of polycrystalline silicon is 120 to 140 Ω/sq., and therefore, a gate resistance at the disconnecting portion of the cobalt silicide layer is about 20 times higher than that at a non-disconnecting portion.

As a method for suppressing the high resistance of the gate due to the disconnection of the silicide layer, for example, there is a method in which a large amount of impurities are added into a conductive film made of polycrystalline silicon to lower a resistance of the conductive film. However, there is a portion using a wire formed of only the conductive film made of the polycrystalline silicon in a circuit unit except for the memory unit of SRAM, and therefore, the amount of impurities added into the conductive film made of the polycrystalline silicon cannot be freely changed.

Also, the disconnection of the silicide layer described above is caused by the following reason. That is, a crystal grain of a part of the polycrystalline silicon is cracked in an upper-surface-edge portion of the conductive film when the gate is formed by processing the conductive film made of the polycrystalline silicon by using dry etching, so that a width of an upper surface of the gate on which the silicide layer is formed becomes narrow in a direction of the gate length. Therefore, if a crystal grain size of the polycrystalline silicon can be made to be smaller than, for example, 20 nm by changing the amount of impurities added into the conductive film made of the polycrystalline silicon to reduce a size of the crack of the crystal grain, it is possible to prevent the disconnection of the silicide layer. However, as described above, the amount of impurities added into the conductive film made of the polycrystalline silicon cannot be freely changed. Even if the amount of impurities can be changed, there arises a problem of a characteristic variation and the like of the field-effect transistor due to a depletion of the conductive film made of the polycrystalline silicon.

An object of the present invention is to provide a technique capable of manufacturing a field-effect transistor having a low-resistance gate with a gate length shorter than 0.1 μm on which a silicide layer is formed without reducing the manufacturing yield.

The above and other objects and novel characteristics of the present invention will be apparent from the description of the present specification and the accompanying drawings.

### Means for Solving the Problems

The typical ones of the inventions disclosed in the present application will be briefly described as follows.

The present invention is a manufacturing method of a field-effect transistor, and the manufacturing method includes: a step for forming a gate insulating film on a surface of a substrate; a step for forming a polycrystalline silicon film on the gate insulating film; a step for converting an upper portion of the polycrystalline silicon film into an amorphous form by ion implantation of an inert gas performed from an upper surface of the polycrystalline silicon film down to a predetermined depth; a step for ion-implanting an impurity of a first conductivity type into the polycrystalline silicon film; a step for forming a gate electrode by processing the polycrystalline silicon film; a step for forming a sidewall formed of an insulating film on a side wall of the gate electrode; a step for forming a source/drain diffusing region by ion-implanting an impurity of the first conductivity type into the substrate with using the gate electrode and the sidewall as a mask; and a step for forming a silicide layer on an upper portion of a silicon film configuring the gate electrode.

The present invention is a field-effect transistor including: a gate insulating film formed on a surface of a substrate; a gate electrode formed of a polycrystalline silicon film and a silicide layer formed on the gate insulating film; and a sidewall formed on a side wall of the gate electrode, and the polycrystalline silicon film configuring the gate electrode contains an inert gas.

### Effects of the Invention

The effects obtained by typical aspects of the present invention will be briefly described below.

Since a silicide layer having a predetermined width can be formed almost uniformly on an upper portion of a gate shorter than 0.1 μm without a disconnection, a field-effect transistor having a low-resistance gate can be manufactured without reducing a manufacturing yield.

### BRIEF DESCRIPTIONS OF THE DRAWINGS

FIG. 1 is a cross section view of a principal part of a semiconductor substrate showing a manufacturing process of a CMOS transistor according to an embodiment of the present invention;

FIG. 2 is a cross section view of a principal part showing the same portion as FIG. 1 in the manufacturing process of the CMOS transistor continued from FIG. 1;

FIG. 3 is a cross section view of a principal part showing the same portion as FIG. 1 in the manufacturing process of the CMOS transistor continued from FIG. 2;

FIG. 4 is a cross section view of a principal part showing the same portion as FIG. 1 in the manufacturing process of the CMOS transistor continued from FIG. 3;

FIG. 5 is a cross section view of a principal part showing the same portion as FIG. 1 in the manufacturing process of the CMOS transistor continued from FIG. 4;

FIG. 6 is a cross section view of a principal part showing the same portion as FIG. 1 in the manufacturing process of the CMOS transistor continued from FIG. 5;

FIG. 7 is a cross section view of a principal part showing the same portion as FIG. 1 in the manufacturing process of the CMOS transistor continued from FIG. 6;

FIG. 8 is a cross section view of a principal part showing the same portion as FIG. 1 in the manufacturing process of the CMOS transistor continued from FIG. 7;

FIG. 9 is a cross section view of a principal part showing the same portion as FIG. 1 in the manufacturing process of the CMOS transistor continued from FIG. 8;

FIG. 10 is a cross section view of a principal part showing the same portion as FIG. 1 in the manufacturing process of the CMOS transistor continued from FIG. 9;

FIG. 11 is a cross section view of a principal part showing the same portion as FIG. 1 in the manufacturing process of the CMOS transistor continued from FIG. 10;

FIG. 12 is a cross section view of a principal part showing the same portion as FIG. 1 in the manufacturing process of the CMOS transistor continued from FIG. 11;

FIG. 13 is a cross section view of a principal part showing the same portion as FIG. 1 in the manufacturing process of the CMOS transistor continued from FIG. 12;

FIG. 14A is an enlarged plan view and enlarged cross section views of a gate electrode of nMIS formed of a polycrystalline silicon film to which nitrogen is ion-implanted, and FIG. 14B is an enlarged plan view and enlarged cross section views of a gate electrode of nMIS formed of a polycrystalline silicon film to which nitrogen is not ion-implanted;

FIG. 15 is a cross section view of a principal part showing the same portion as FIG. 1 in the manufacturing process of the CMOS transistor continued from FIG. 13;

FIG. 16 is a cross section view of a principal part showing the same portion as FIG. 1 in the manufacturing process of the CMOS transistor continued from FIG. 15; and

FIG. 17A and FIG. 17B are graph diagrams each showing a relation of a capacitance (C) and a gate applied voltage (Vg) of nMIS and pMIS, respectively.

### BEST MODE FOR CARRYING OUT THE INVENTION

In the embodiment described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiment described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiment described below, it goes without saying that the components (including element steps) are not always indispensable unless otherwise stated or except the case where the components are apparently indispensable in principle. Similarly, in the embodiment described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Still further, in the present embodiment, a MISFET (Metal Insulator Semiconductor Field Effect Transistor) representing a field-effect transistor is abbreviated as MIS, a p-channel type MISFET is abbreviated as pMIS, and an n-channel type MISFET is abbreviated as nMIS. Still further, even if a MOS is cited for conveniences, a non-oxide film is not eliminated. Still further, in the present embodiment, when a wafer is described, a Si (Silicon) single crystal wafer is mainly indicated. However, the wafer is not limited to only that but widely indicates a SOI (Silicon On Insulator) wafer, an insulating film substrate for forming an integrated circuit thereon, and the like. A shape of the wafer is not limited to only a circle shape or almost circle shape, but includes a square shape, a rectangle shape, and the like. Still further, when a silicon film, a silicon portion, a silicon member, and the like are described, it is needless to say that they include not only a pure silicon but also a silicon containing an impurity and a silicon containing an additive, for example, an alloy such as SiGe and SiGeC having a silicon as one of main components thereof (including a strained silicon) unless otherwise stated or in the case where they are apparently excluded.

Still further, components having the same function are denoted by the same reference symbols throughout the drawings for describing the embodiment, and the repetitive description thereof will be omitted. The embodiment of the present invention will be described in detail with reference to the accompanying drawings.

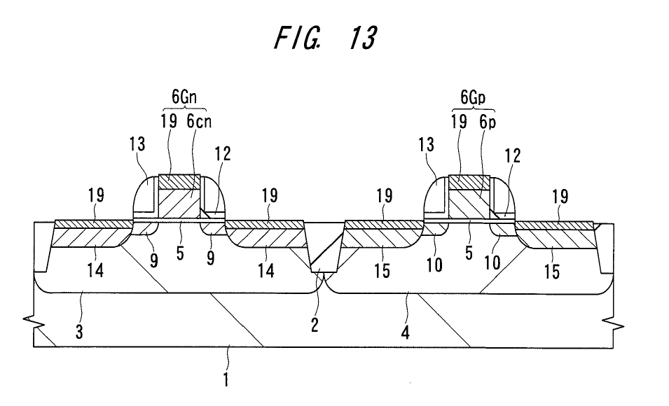

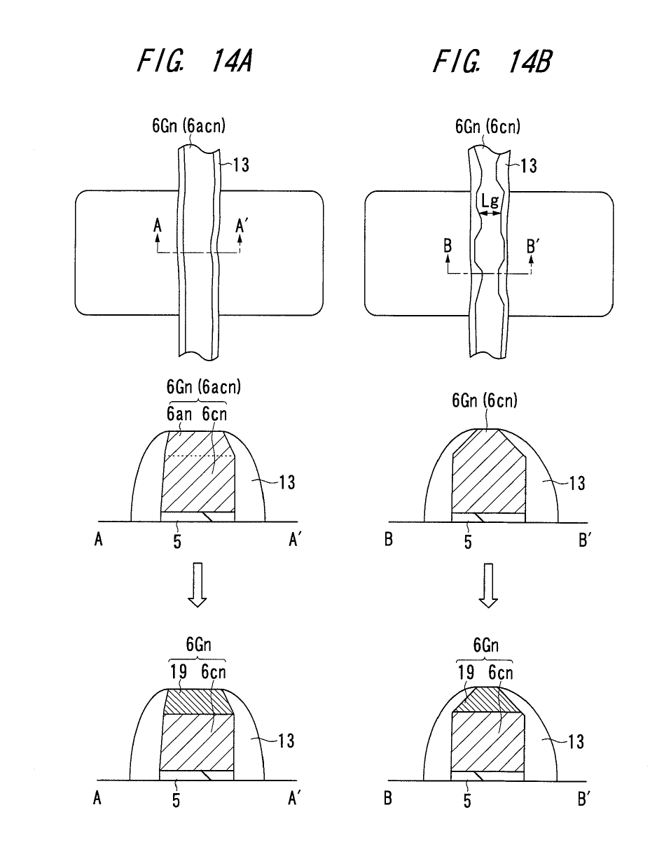

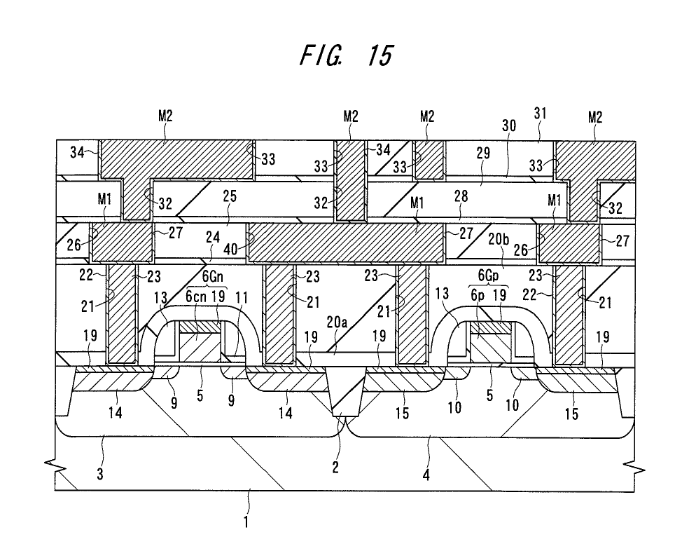

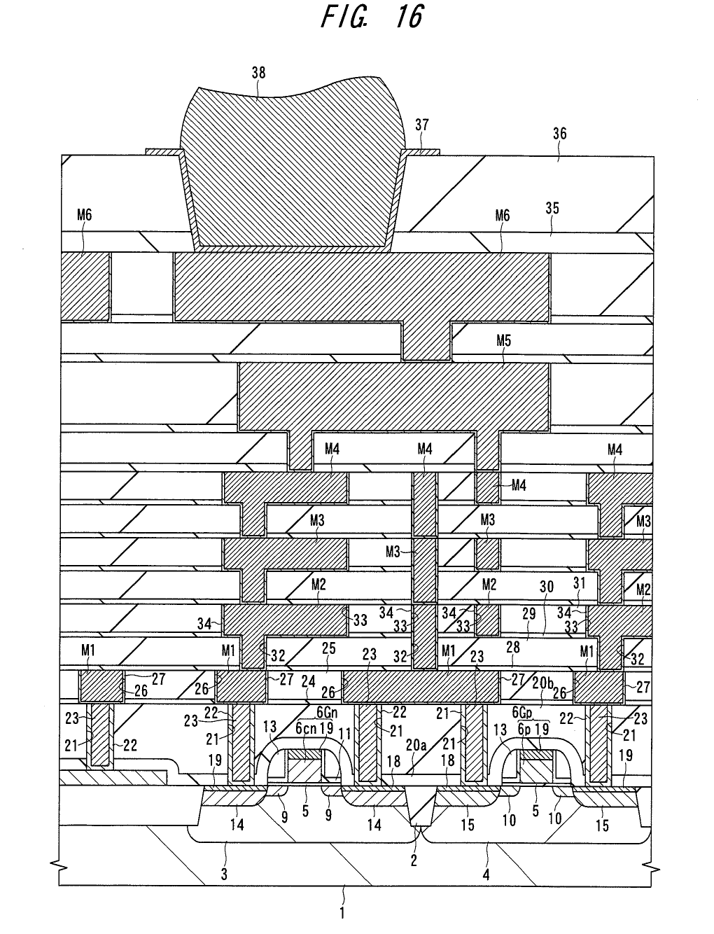

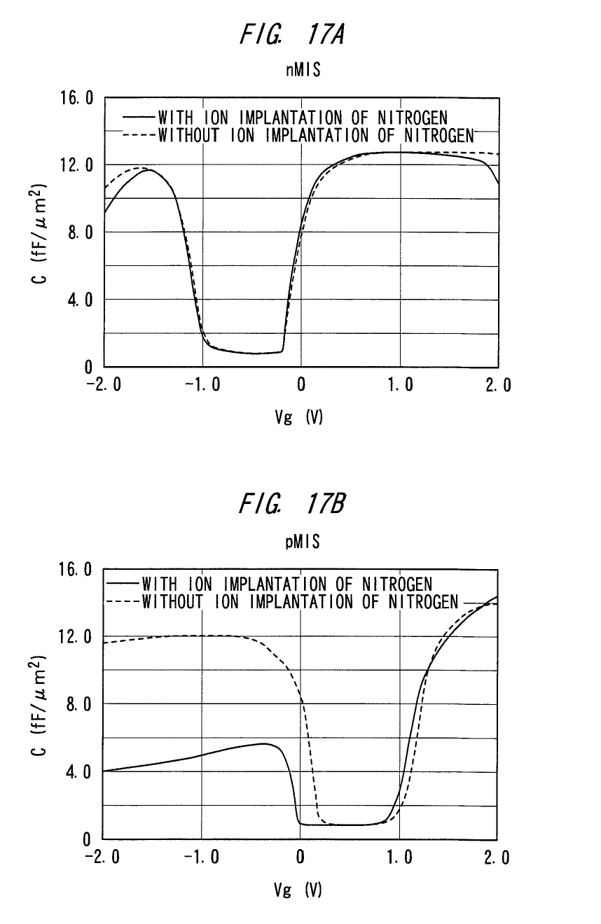

A manufacturing method of a CMOS (Complementary Metal Oxide Semiconductor) device according to a first embodiment of the present invention will be described with reference to FIG. 1 to FIG. 17. FIG. 1 to FIG. 13, FIG. 15, and FIG. 16 are cross section views of a principle part of the CMOS device. FIG. 14A and FIG. 14B are an enlarged plan view and enlarged cross section views of a gate electrode of nMIS formed of a polycrystalline silicon film to which nitrogen is ion-implanted, and an enlarged plan view and enlarged cross section views of a gate electrode of nMIS formed of a polycrystalline silicon film to which nitrogen is not ion-implanted, respectively. FIG. 17A and FIG. 17B are graph diagrams each showing a relation of a capacitance (C) and a gate applied voltage (Vg) of nMIS and pMIS, respectively.

First, as shown in FIG. 1, a semiconductor substrate (semiconductor thin plate with a substantially circle shape in plane which is called a semiconductor wafer) 1 made of, for example, p-type single crystal silicon is prepared. Next, a device isolation region 2 is formed on a main surface of the semiconductor substrate 1. The device isolation region 2 is formed by etching the semiconductor substrate 1 to form a trench having a depth of 0.35 μm followed by depositing an insulating film, for example, a silicon oxide film by CVD (Chemical Vapor Deposition) method on the main surface of the semiconductor substrate 1, and then, removing the silicon oxide film located outside the trench by CMP (Chemical Mechanical Polishing) method.

Next, a pMIS forming region is covered by a resist pattern, and a p-type impurity, for example, boron (B) is ion-implanted into an nMIS forming region in the semiconductor substrate 1. Similarly, the nMIS forming region is covered by a resist pattern, and an n-type impurity, for example, phosphorus (P) or Arsenic (As) is ion-implanted into the pMIS forming region in the semiconductor substrate 1. And then, a thermal process is performed to the semiconductor substrate 1 to activate the p-type impurity and the n-type impurity, thereby forming a p-type well 3 in the nMIS forming region and an n-type well 4 in the pMIS forming region. An impurity ion for controlling the threshold value of nMIS or pMIS may be ion-implanted into the p-type well 3 or the n-type well 4.

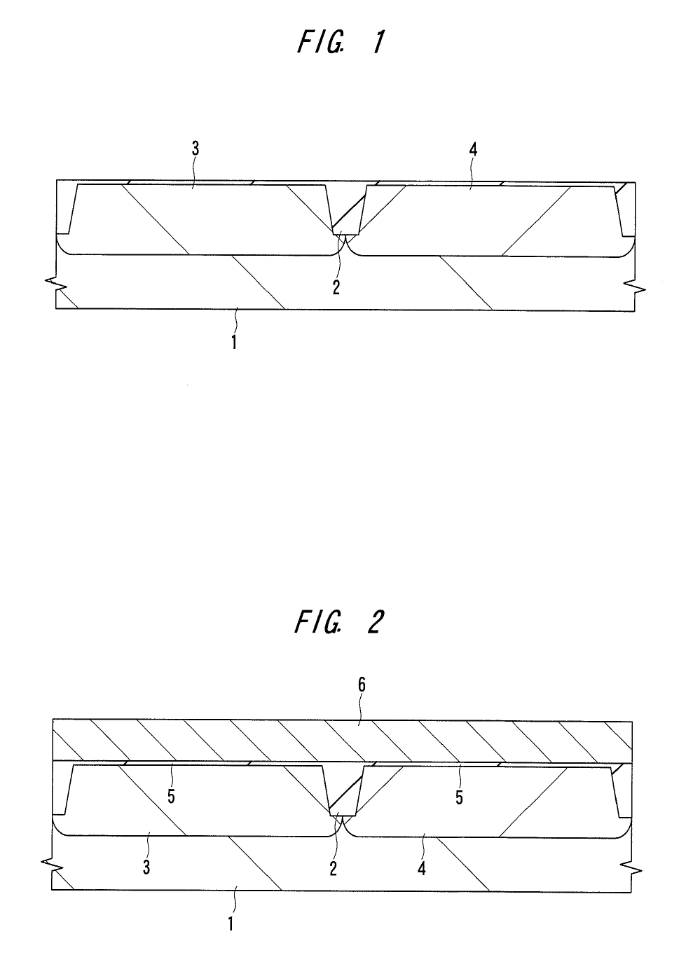

Next, as shown in FIG. 2, after cleaning the surface of the semiconductor substrate 1 by wet etching using, for example, a hydrofluoric acid (HF) aqueous solution, a thermal oxidation is performed to the semiconductor substrate 1, thereby forming a gate insulating film 5 having a thickness of, for example, about 5 nm on the surface of the semiconductor substrate 1 (surfaces of the p-type well 3 and the n-type well 4). Subsequently, a polycrystalline silicon film 6 having a thickness of, for example, about 180 nm is deposited by CVD method on the gate insulating film 5. A crystal grain size of the polycrystalline silicon film 6 is smaller than 20 nm, and an amorphous silicon film may be deposited instead of the polycrystalline silicon film 6.

Next, as shown in FIG. 3, the nMIS forming region is covered by a resist pattern 7, and a p-type impurity, for example, boron is ion-implanted into the polycrystalline silicon film 6 in the pMIS forming region. A condition of the ion implantation of boron is, for example, energy of 5 keV and dose of 1×10¹⁵ cm⁻².

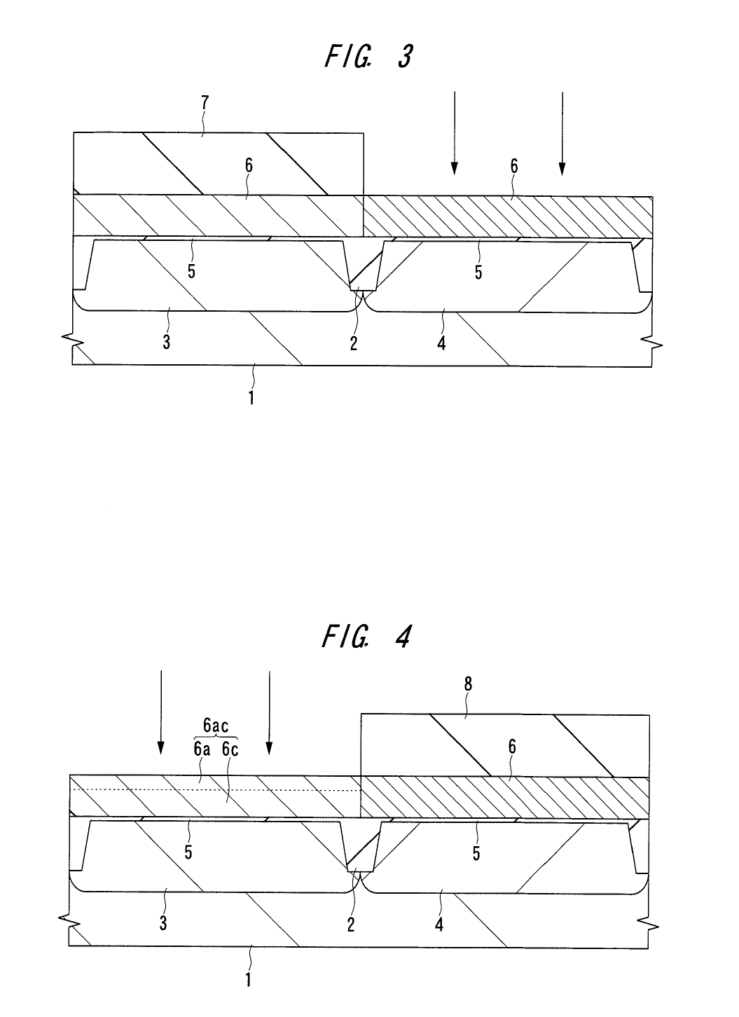

Next, after removing the resist pattern 7, as shown in FIG. 4, the pMIS forming region is covered by a resist pattern 8, and an inert gas, for example, nitrogen (N₂) is ion-implanted into the polycrystalline silicon film 6 in the nMIS forming region from an upper surface of the polycrystalline silicon film 6 down to a depth of about 60 nm (Rp=33 nm in a case of a single crystal Si). By this means, a portion from the upper surface of the polycrystalline silicon film 6 down to a predetermined depth, for example, about 50 to 60 nm is converted to an amorphous form. In FIG. 4, a silicon layer of the amorphous structure is indicated by a symbol 6a and a silicon layer of the polycrystalline structure is indicated by a symbol 6c, and a silicon film of a two layer structure is indicated by an amorphous/polycrystalline silicon film 6ac in order to distinguish it from the polycrystalline silicon film 6 entirely made of polycrystalline silicon.

A condition of the ion implantation of nitrogen is, for example, energy of 1 to 50 keV and dose of 5×10¹⁴ cm⁻² or more. For the polycrystalline silicon film 6 having the thickness of 180 nm, if nitrogen is ion-implanted with the energy higher than 50 keV into the polycrystalline silicon film 6, the nitrogen reaches an interface between the gate insulating film 5 and the semiconductor substrate 1 (p-type well 3) to cause a change of an operation characteristic of nMIS or the upper portion of the polycrystalline silicon film 6 is not converted to the amorphous form. For these reasons, it is considered that, for example, 1 to 50 keV is a proper range for the energy of the ion implantation of nitrogen (it is needless to say that the range is not limited depending on other conditions). Also, a range of 5 to 40 keV is considered as a proper range for a mass production, and further, a range of 20 to 35 keV or the like in which 30 keV is a center value is considered as the most preferable range.

Note that, the inert gas is not limited to nitrogen but may be, for example, helium (He), neon (Ne), argon (Ar), krypton (Kr), xenon (Xe), radon (Rn), and the like which are elements of the group 18 of the periodic table. A condition of an ion implantation of argon into the polycrystalline silicon film 6 is, for example, energy of 1 to 100 keV and dose of 5×10¹⁴ cm⁻² or more.

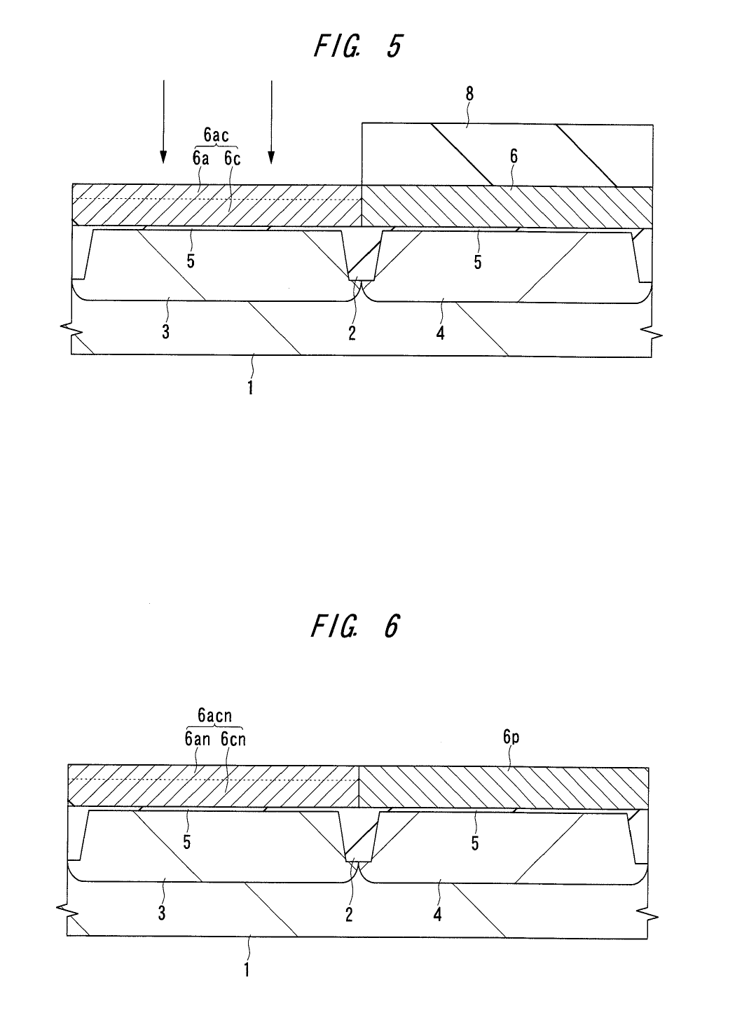

Next, as shown in FIG. 5, in a state of covering the pMIS forming region by the resist pattern 8, an n-type impurity, for example, phosphorous is ion-implanted into the amorphous/polycrystalline silicon film 6ac in the nMIS forming region. A condition of the ion implantation of phosphorous is, for example, energy of 20 keV and dose of 1×10¹⁵ cm².

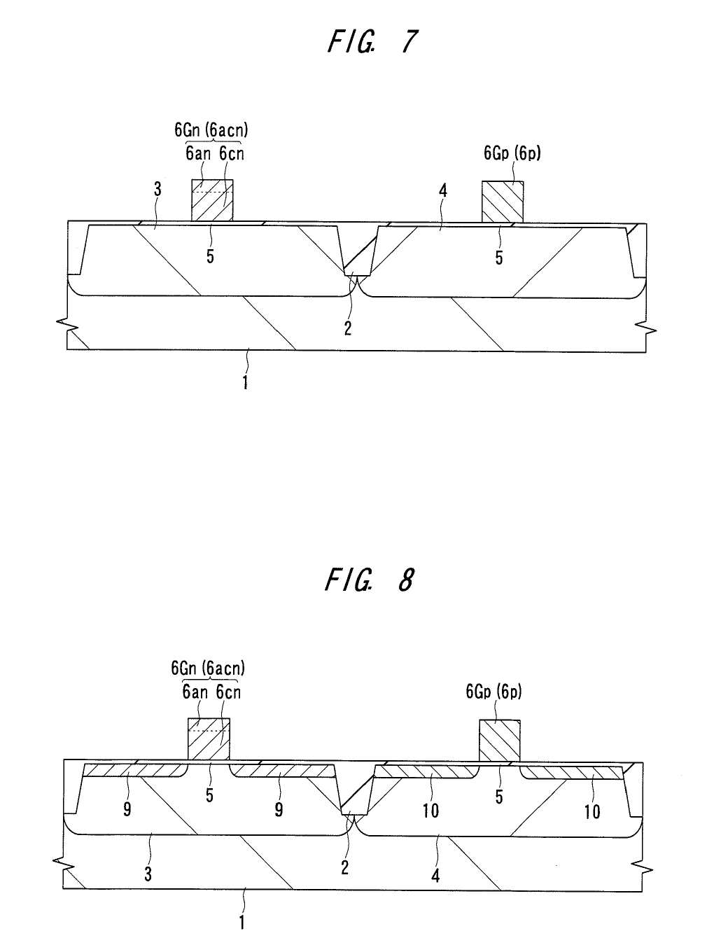

Next, as shown in FIG. 6, after removing the resist pattern 8, a thermal process at the temperature of about 900° C. is performed for about 0 to 30 seconds to the semiconductor substrate 1 by using RTA (Rapid Thermal Anneal) method, thereby recovering damage due to ion irradiation, and at the same time, activating the p-type impurity ion-implanted into the polycrystalline silicon film 6 in the pMIS forming region to form a p-type polycrystalline silicon film 6p and activating the n-type impurity ion-implanted into the amorphous/polycrystalline silicon film 6ac in the nMIS forming region to form an n-type amorphous/polycrystalline silicon film 6acn. At this time, the nitrogen ion-implanted into the amorphous/polycrystalline silicon film 6ac in the nMIS forming region is not activated, and the nitrogen remains inside the n-type amorphous/polycrystalline silicon film 6acn. Although a slight growth of crystal grain sizes of the p-type polycrystalline silicon film 6p in the pMIS forming region and the n-type amorphous/polycrystalline silicon film 6acn in the nMIS forming region is seen by the thermal process, the p-type polycrystalline silicon film 6p in the pMIS forming region is configured with a polycrystalline structure having a crystal grain size smaller than 20 nm, the n-type amorphous silicon film 6an of the n-type amorphous/polycrystalline silicon film 6acn in the nMIS forming region is configured with a polycrystalline structure having a crystal grain size of about 20 nm, and an n-type polycrystalline silicon film 6cn is configured with a polycrystalline structure having a crystal grain size of about 20 to 40 nm. Note that the n-type amorphous silicon film 6an of the n-type amorphous/polycrystalline silicon film 6acn in the nMIS forming region is not crystallized in some cases depending on a condition of the thermal process.

Next, as shown in FIG. 7, the n-type amorphous/polycrystalline silicon film 6acn is processed by dry etching with using a resist pattern as a mask to form a gate electrode 6Gn formed of the n-type amorphous/polycrystalline silicon film 6acn and having a gate length of about 0.085 μm in the nMIS forming region. At the same time, the p-type polycrystalline silicon film 6p is processed by dry etching with using a resist pattern as a mask to form a gate electrode 6Gp formed of the p-type polycrystalline silicon film 6p and having a gate length of about 0.085 μm in the pMIS forming region.

Since the upper portion of the n-type amorphous/polycrystalline silicon film 6acn is configured with the polycrystalline structure formed of the crystal grain size smaller than 20 nm, it is possible to prevent a crack on an upper-surface-edge portion of the gate electrode 6Gn formed of the polycrystalline silicon film 6acn processed by the dry etching. Similarly, since the crystal grain size of the p-type polycrystalline silicon film 6p is smaller than 20 nm, it is possible to prevent a crack on an upper-surface-edge portion of the gate electrode 6Gp formed of the p-type polycrystalline silicon film 6p processed by dry the etching.

Next, as shown in FIG. 8, after covering the pMIS forming region by a resist pattern, an n-type impurity, for example, phosphorous or arsenic is ion-implanted into the nMIS forming region on the semiconductor substrate 1 with using the gate electrode 6Gn of nMIS as a mask to form a source/drain diffusing region 9 having a relatively low concentration of nMIS. Similarly, after covering the nMIS forming region by a resist pattern, a p-type impurity, for example, boron difluoride (BF₂) is ion-implanted into the pMIS forming region on the semiconductor substrate 1 with using the gate electrode 6Gp of pMIS as a mask to form a source/drain diffusing region 10 having a relatively low concentration of pMIS. Depths of the source/drain diffusing regions 9 and 10 described above are, for example, about 30 nm.

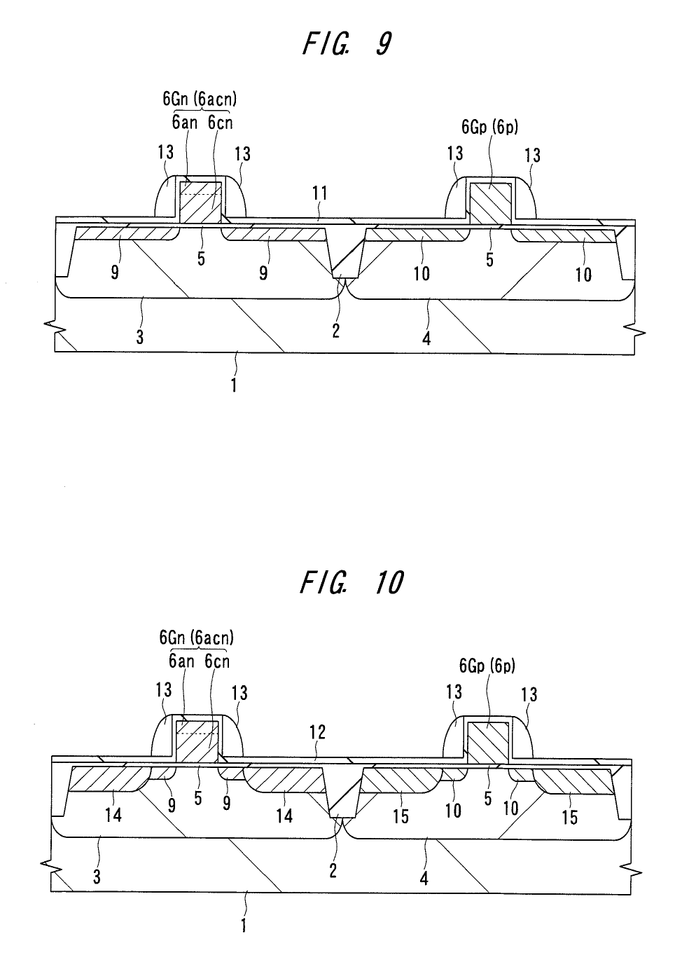

Next, as shown in FIG. 9, after depositing a silicon oxide film 11 having a thickness of, for example, about 10 nm by CVD method on the main surface of the semiconductor substrate 1, a silicon nitride film is further deposited by CVD method on the silicon oxide film 11. Subsequently, the silicon nitride film is anisotropically etched by RIE (Reactive Ion Etching) method to form a sidewall 13 on each of side walls of the gate electrode 6Gn of nMIS and the gate electrode 6Gp of pMIS.

Next, as shown in FIG. 10, after covering the pMIS forming region by a resist pattern, an n-type impurity, for example, arsenic is ion-implanted into the p-type well 3 with using the gate electrode 6Gn of nMIS and the sidewall 13 as a mask to form a source/drain diffusing region 14 having a relatively high concentration of nMIS. Similarly, after covering the nMIS forming region by a resist pattern, a p-type impurity, for example, boron difluoride is ion-implanted into the n-type well 4 with using the gate electrode 6Gp of pMIS and the sidewall 13 as a mask to form a source/drain diffusing region 15 having a relatively high concentration of pMIS. Depths of the source/drain diffusing regions 14 and 15 described above are, for example, about 50 nm.

Next, a thermal process at a temperature of about 1000° C. is performed for about 1 second to the semiconductor substrate 1 by using RTA method, thereby recovering damage due to ion irradiation, and at the same time, activating the p-type impurity ion-implanted into the n-type well 4 in the pMIS forming region and the n-type impurity ion-implanted into the p-type well 3 in the nMIS forming region. At this time, the nitrogen inside the n-type amorphous silicon film 6an and the n-type polycrystalline silicon film 6cn in the nMIS forming region is not activated, and the nitrogen remains inside the gate electrode 6Gn of nMIS.

Next, a cobalt silicide layer with low resistance of, for example, about 10 Ω/sq. is formed by salicide technique on the surfaces of the gate electrode 6Gn and the source/drain diffusing region 14 of nMIS and on the surfaces of the gate electrode 6Gp and the source/drain diffusing region 15 of pMIS.

First, as shown in FIG. 11, after exposing the surfaces of the gate electrode 6Gn and the source/drain diffusing region 14 of nMIS and the surfaces of the gate electrode 6Gp and the source/drain diffusing region 15 of pMIS, a cobalt film 16 and a titanium nitride film 17 are sequentially deposited by sputtering method on the main surface of the semiconductor substrate 1. A thickness of the cobalt film 16 is, for example, about 8 nm, and a thickness of the titanium nitride film 17 is, for example, about 15 nm. The titanium nitride film 17 is provided on the cobalt film 16 for preventing the oxidation of the cobalt film 16, and a titanium film can be used instead of the titanium nitride film 17.

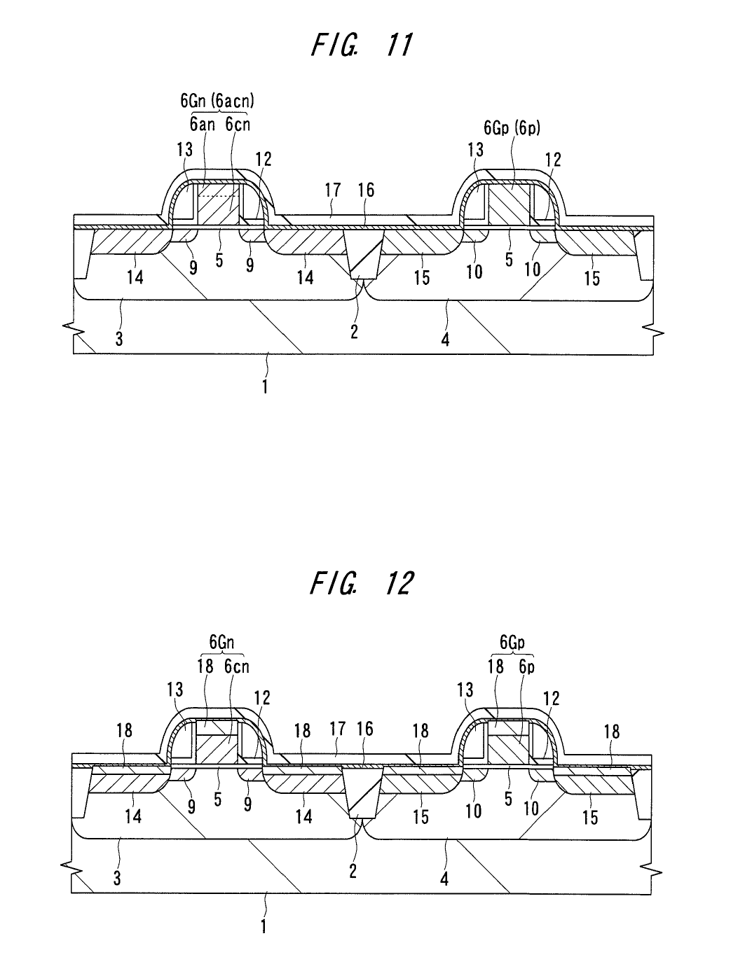

Next, as shown in FIG. 12, a thermal process at a temperature of about 480° C. is performed for about 30 seconds to the semiconductor substrate 1 to selectively cause a reaction between the cobalt film 16 and the n-type amorphous/polycrystalline silicon film 6acn configuring the gate electrode 6Gn of nMIS and between the cobalt film 16 and the single crystal silicon configuring the semiconductor substrate 1 on which the source/drain diffusing region 14 of nMIS is formed, thereby forming a cobalt silicide (CoSi) layer 18. Similarly, by selectively causing a reaction between the cobalt film 16 and the p-type polycrystalline silicon film 6p configuring the gate electrode 6Gp of pMIS and between the cobalt film 16 and the single crystal silicon configuring the semiconductor substrate 1 on which the source/drain diffusing region 15 of pMIS is formed, a cobalt silicide (CoSi) layer 18 is formed.

At this time, if the n-type polycrystalline silicon film 6acn contains a large amount of nitrogen, the reaction between cobalt and silicon is blocked by nitrogen and the cobalt silicide (CoSi) layer 18 having a desired thickness is not formed, so that there arises a problem that a desired resistance cannot be obtained in the gate electrode 6Gn of nMIS having a cobalt silicide (CoSi₂) layer to be formed later on its upper portion. Although the dose of nitrogen ion-implanted into the polycrystalline silicon film 6 is set to 5×10¹⁴ cm⁻² or more in the present embodiment, an upper limit of the dose is desired to be set to a value not blocking the formation of the cobalt silicide (CoSi) layer 18, for example, 5×10¹⁵ cm⁻² or less.

Also, the silicon on the upper portion of the n-type amorphous/polycrystalline silicon film 6acn is taken into the cobalt film 16, thereby forming the cobalt silicide (CoSi) layer 18. Therefore, the silicon of the n-type amorphous silicon layer 6an is taken into the cobalt film 16, so that the cobalt silicide (CoSi) layer 18 is formed, and therefore, the gate electrode 6Gn of nMIS after forming the cobalt silicide (CoSi) layer 18 is configured with a stacked structure of the cobalt silicide (CoSi) layer 18 and the polycrystalline silicon layer 6cn.

Next, as shown in FIG. 13, after removing an unreacted cobalt film 16 and an unreacted titanium nitride film 17 by wet cleaning using sulfuric acid, wet cleaning using sulfuric acid and hydrogen peroxide, or the like, a thermal process at a temperature of about 700° C. is performed for about 60 seconds to the semiconductor substrate 1, thereby forming a cobalt silicide (CoSi₂) layer 19 having a resistance of about 6 to 8 Ω/sq. Note that, although a part of the nitrogen ion-implanted into the polycrystalline silicon film 6 comes out due to each of the thermal processes performed to the semiconductor substrate 1, most of the nitrogen remains inside the n-type polycrystalline silicon film 6cn.

FIG. 14A shows an enlarged plan view of the gate electrode of nMIS formed of the polycrystalline silicon to which nitrogen is ion-implanted, an enlarged cross section view of the gate electrode when the silicide layer is not formed in a line A-A′ of the enlarged plan view, and an enlarged cross section view of the gate electrode when the silicide layer is formed. As described above, since the crack on the upper-surface-edge portion of the gate electrode 6Gn is small or does not exist, a cross sectional shape of the gate electrode 6Gn of nMIS is substantially a rectangle shape or a trapezoidal shape though depending on the condition of dry etching. Therefore, a cobalt silicide (CoSi₂) layer 19 having a predetermined width can be formed almost uniformly without a disconnection on the upper portion of the gate electrode 6Gn after forming the sidewall 13. In this manner, the gate electrode 6Gn with low resistance can be obtained.

For the comparison with FIG. 14A, FIG. 14B shows an enlarged plan view of the gate electrode of nMIS formed of the polycrystalline silicon to which nitrogen is not ion-implanted, an enlarged cross section view of the gate electrode when the silicide layer is not formed in a line B-B′ of the enlarged plan view, and an enlarged cross section view of the gate electrode when the silicide layer is formed. In the gate electrode of nMIS formed of the polycrystalline silicon to which nitrogen is not ion-implanted, the crack is likely to occur on the upper-surface-edge portion of the gate electrode. When the crack exits on the upper-surface-edge portion of the gate electrode 6Gn, a width in a gate length direction (Lg in FIG. 14B) on the upper surface of the gate electrode 6Gn in which the silicide layer is formed after forming the sidewall 13 is decreased, and therefore, the gate electrode 6Gn has high resistance. When the crack is larger, the cobalt silicide (CoSi₂) layer 19 is disconnected, so that the resistance of the gate electrode 6Gn becomes almost equal to the resistance of the n-type polycrystalline silicon film 6cn.

Note that, although the crack on the upper-surface-edge portion of the gate electrode 6Gn of nMIS disappears by the ion implantation of nitrogen, the reaction in the formation of the cobalt silicide (CoSi) layer 18 is blocked by the nitrogen as described above, so that the cobalt silicide (CoSi) layer 18 with a desired thickness, that is, the cobalt silicide (CoSi₂) layer 19 with a desired resistance is not formed, and there is a possibility that the resistance of the gate electrode 6Gn is increased. However, by using the formation condition of the n-type amorphous/polycrystalline silicon film 6acn and the formation condition of the cobalt silicide (CoSi₂) layer 19 described in the present embodiment, the gate electrode 6Gn having the cobalt silicide (CoSi₂) layer 19 with the desired resistance formed thereon can be formed. For example, a sheet resistance of a gate electrode in which a cobalt silicide (CoSi₂) layer is formed on the upper portion of a polycrystalline silicon film to which phosphorous is ion-implanted with energy of 20 keV and dose of 6.0×10¹⁵ cm⁻² is 5.5 Ω/sq., and for example, a sheet resistance of a gate electrode in which a cobalt silicide (CoSi₂) layer is formed on the upper portion of the polycrystalline silicon film to which phosphorous is ion-implanted with energy of 20 keV and dose of 6.0×10¹⁵ cm⁻² and nitrogen is ion-implanted with energy of 20 keV and dose of 6.0×10¹⁵ cm⁻² is 7.5 Ω/sq. Accordingly, although increase of the resistance due to the ion implantation of nitrogen is observed, the sheet resistance of 10 Ω/sq. or lower can be obtained.

After forming the low-resistance cobalt silicide (CoSi₂) layer 19 on the surfaces of the gate electrode 6Gn and the source/drain diffusing region 14 of nMIS and on the surfaces of the gate electrode 6Gp and the source/drain diffusing region 15 of pMIS, wires electrically connecting a CMOS device and various semiconductor elements formed on the semiconductor substrate 1 are formed.

Next, as shown in FIG. 15, a silicon nitride film is deposited by CVD method on the main surface of the semiconductor substrate 1 to form a first insulating film 20a. Subsequently, a TEOS (Tetra Ethyl Ortho Silicate) film is deposited by plasma CVD method on the first insulating film 20a to form a second insulating film 20b, thereby forming an interlayer insulating film formed of the first and second insulating films 20a and 20b. And then, a surface of the second insulating film 20b is polished by CMP method. Even if concave and convex shape caused by an underlying surface roughness is formed on the surface of the first insulating film 20a, an interlayer insulating film whose surface is flattened can be obtained by polishing the surface of the second insulating film 20b by CMP method.

Next, the first and second insulating films 20a and 20b are etched with using a resist pattern as a mask to form contact holes 21 reaching the cobalt silicide layers 19 of nMIS and pMIS at predetermined positions. Subsequently, a barrier metal film 22 is formed on the main surface of the semiconductor substrate 1. The barrier metal film 22 is formed of, for example, a titanium film, a titanium nitride film, and the like. Further, a metal film, for example, a tungsten film is deposited on the barrier metal film 22, and then, a surface of the metal film is flattened by, for example, CMP method, thereby filling the insides of the contact holes 21 with the metal film to form plugs 23.

Next, a stopper insulating film 24 and an insulating film for a wire formation 25 are sequentially formed on the main surface of the semiconductor substrate 1. The stopper insulating film 24 is a film to be an etching stopper in a trench process to the insulating film 25, and a material having etching selectivity to the insulating film 25 is used for the stopper insulating film 24. The stopper insulating film 24 can be, for example, a silicon nitride film formed by plasma CVD method, and the insulating film 25 can be, for example, a silicon oxide film formed by plasma CVD method.

Next, a wire of a first layer is formed by single damascene method. First, after forming a wire trench 26 in a predetermined region of the stopper insulating film 24 and the insulating film 25 by dry etching using a resist pattern as a mask, a barrier metal film 27 is formed on the main surface of the semiconductor substrate 1. Subsequently, a seed layer of copper is formed on the barrier metal film 27 by CVD method or sputtering method, and further, a copper plating film is formed on the seed layer by using electroplating method. An inside of the wire trench 26 is filled with the copper plating film. Subsequently, the copper plating film, the seed layer, and the barrier metal film 27 in a region other than the wire trench 26 are removed by CMP method to form a wire M1 of the first layer using a copper film as a main conductive material.

Next, a wire of a second layer is formed by dual damascene method. First, a cap insulating film 28, an interlayer insulating film 29, and a stopper insulating film for a wire formation 30 are sequentially formed on the main surface of the semiconductor substrate 1. Contact holes are formed in the cap insulating film 28 and the interlayer insulating film 29 as described later. The cap insulating film 28 is made of a material having etching selectivity to the interlayer insulating film 29, and can be, for example, a silicon nitride film formed by plasma CVD method. Further, the cap insulating film 28 has a function as a protection film for preventing diffusion of copper configuring the wire M1 of the first layer. The interlayer insulating film 29 can be, for example, a TEOS film formed by plasma CVD method. The stopper insulating film 30 is made of an insulating material having etching selectivity to the interlayer insulating film 29 and an insulating film for a wire formation deposited on an upper layer of the stopper insulating film 30 at a later stage, and can be, for example, a silicon nitride film formed by plasma CVD method.

Next, after processing the stopper insulating film 30 by dry etching using a resist pattern for a hole formation as a mask, an insulating film for a wire formation 31 is formed on the stopper insulating film 30. The insulating film 31 can be, for example, a TEOS film.

Next, the insulating film 31 is processed by dry etching using a resist pattern for a wire trench formation as a mask. At this time, the stopper insulating film 30 functions as an etching stopper. Subsequently, the interlayer insulating film 29 is processed by dry etching using the stopper insulating film 30 and a resist pattern for a wire trench formation as a mask. At this time, the cap insulating film 28 functions as an etching stopper. Subsequently, by removing the exposed cap insulating film 28 by dry etching, contact holes 32 are formed in the cap insulating film 28 and the interlayer insulating film 29, and wire trenches 33 are formed in the stopper insulating film 30 and the insulating film 31.

Next, a wire of the second layer is formed inside the contact holes 32 and the wire trenches 33. The wire of the second layer is made of a barrier metal layer and a copper film serving as the main conductive material, and a connection member between this wire and the wire M1 of the first layer which is the wire in a lower layer is integrally formed with the wire of the second layer. First, a barrier metal film 34 is formed on the main surface of the semiconductor substrate 1 including the inside of the contact hole 32 and the wire trench 33. The barrier metal film 34 is, for example, a titanium nitride film, a tantalum nitride film, a stacked film obtained by stacking a tantalum film on a tantalum nitride film or a stacked film obtained by stacking a ruthenium film on a tantalum nitride film. Subsequently, a seed layer of copper is formed on the barrier metal film 34 by CVD method or sputtering method, and further, a copper plating film is formed on the seed layer by using electroplating method. Insides of the contact holes 32 and the wire trenches 33 are filled with the copper plating film. Subsequently, the copper plating film, the seed layer, and the barrier metal film 34 in a region other than the contact holes 32 and the wire trenches 33 are removed by CMP method to form a wire M2 of the second layer using a copper film as a main conductive material.

And then, as shown in FIG. 16, wires of further upper layers are formed by, for example, a similar method to the wire M2 of the second layer described above. A CMOS device in which wires M3, M4, M5, and M6 of a third layer to a sixth layer are formed is exemplified in FIG. 16. Subsequently, a silicon nitride film 35 is formed on the wire M6 of the sixth layer, and a silicon oxide film 36 is formed on the silicon nitride film 35. These silicon nitride film 35 and silicon oxide film 36 function as a passivation film for preventing an invasion of water and impurities and suppressing a transmission of α-ray from outside.

Next, the silicon nitride film 35 and the silicon oxide film 36 are processed by etching using a resist pattern as a mask to expose a part of the wire M6 of the sixth layer (bonding pad portion). Subsequently, a bump base electrode 37 formed of a stacked layer of a gold film, a nickel film, and the like is formed on the exposed wire M6 of the sixth layer, and then, a bump electrode 38 made of gold, solder, or the like is formed on the bump base electrode 37, thereby substantially completing the CMOS device according to the present embodiment. Note that the bump electrode 38 is an electrode for external connection. And then, the semiconductor wafer is diced into individual semiconductor chips, and the chip is mounted on a package substrate and the like, thereby completing the semiconductor device. However, descriptions thereof are omitted.

Note that, although the n-type impurity is ion-implanted after ion-implanting the inert gas into the polycrystalline silicon film 6 in the nMIS forming region in the present embodiment, the inert gas may be ion-implanted after ion-implanting the n-type impurity.

Also, nitrogen is ion-implanted into the polycrystalline silicon film 6 in the nMIS forming region to convert the portion from the upper surface down to a predetermined depth of the polycrystalline silicon film 6 into amorphous form in the present embodiment. However, an inert gas, for example, nitrogen or element of the group 18 of the periodic table such as helium, neon, argon, krypton, xenon or radon may be ion-implanted into the polycrystalline silicon film 6 in the pMIS forming region to convert the portion from the upper surface down to a predetermined depth of the polycrystalline silicon film 6 into amorphous form. However, since the p-type polycrystalline silicon film 6p to which a p-type impurity has been ion-implanted is likely to be depleted when the inert gas is ion-implanted, ion implantation conditions different from each other have to be adopted in the addition of the inert gas into the polycrystalline silicon film 6 in the pMIS forming region and the addition of the impurity into the polycrystalline silicon film 6 in the nMIS forming region.

FIG. 17 shows an example of C-V characteristic of polycrystalline silicon films to which nitrogen is ion-implanted. FIG. 17A shows a relation of a capacitance (C) and a gate applied voltage (Vg) in nMIS having a gate electrode formed of an n-type polycrystalline silicon film to which nitrogen is ion-implanted and nMIS having a gate electrode formed of an n-type polycrystalline silicon film to which nitrogen is not ion-implanted, and FIG. 17B shows a relation of a capacitance (C) and a gate applied voltage (Vg) in pMIS having a gate electrode formed of a p-type polycrystalline silicon film to which nitrogen is ion-implanted and pMIS having a gate electrode formed of a p-type polycrystalline silicon film to which nitrogen is not ion-implanted. Conditions of the ion implantations of nitrogen added into the n-type polycrystalline silicon film and the p-type polycrystalline silicon film are the same, and the conditions are, for example, energy of 20 keV and dose of 5.0×10¹⁵ cm⁻².

As shown in FIG. 17A, the depletion of the n-type polycrystalline silicon film due to the ion implantation of nitrogen is not found in the nMIS having the gate electrode formed of the n-type polycrystalline silicon film. Meanwhile, as shown in FIG. 17B, a capacitance of the gate electrode formed of the p-type polycrystalline silicon film to which nitrogen is ion-implanted is lowered in the pMIS having the gate electrode formed of the p-type polycrystalline silicon film, and the depletion of the polycrystalline silicon film is found. Therefore, when the ion implantation is performed to the polycrystalline silicon film in the pMIS forming region, the dose and the energy of the inert gas are desired to be optimized from the condition of the inert gas ion-implanted into the polycrystalline silicon film in the nMIS forming region.

As described above, according to the present embodiment, the n-type polycrystalline silicon film 6acn having the amorphous structure or the polycrystalline structure formed of the crystal grain size smaller than 20 nm on the upper portion thereof is processed by dry etching, thereby capable of preventing the crack on the upper-surface-edge portion of the gate electrode 6Gn. In this manner, the cobalt silicide (CoSi₂) layer 19 having a predetermined width can be formed almost uniformly without the disconnection on the upper surface of the gate electrode 6Gn after forming the sidewall 13, thereby capable of preventing the increase in the resistance of the gate electrode 6Gn. Therefore, when the invention of this application is applied to, for example, nMIS configuring a memory unit of SRAM, the occurrence of single bit defect can be prevented, and the manufacturing yield can be improved.

In the foregoing, the invention made by the inventors of the present invention has been concretely described based on the embodiment. However, it is needless to say that the present invention is not limited to the foregoing embodiment and various modifications and alterations can be made within the scope of the present invention.

### INDUSTRIAL APPLICABILITY

The present invention can be applied to a semiconductor product provided with a field-effect transistor having silicide on polycrystalline silicon.

1. A manufacturing method of a semiconductor device forming a field-effect transistor of a first conductivity type, comprising the following steps:
(a) a step for forming a gate insulating film on a surface of a substrate of a second conductivity type different from the first conductivity type;
(b) a step for forming a silicon film on the gate insulating film;
(c) a step for ion-implanting an impurity of the first conductivity type into the silicon film;
(d) a step for forming a gate electrode by processing the silicon film after the step (c);
(e) a step for forming a sidewall formed of an insulating film on a side wall of the gate electrode;
(f) a step for ion-implanting the impurity of the first conductivity type into the substrate with using the gate electrode and the sidewall as a mask; and
(g) a step for forming a silicide layer on an upper portion of the silicon film configuring the gate electrode, and
further comprising the following step between the step (b) and the step (c) or between the step (c) and the step (d):
(h) a step for ion-implanting an inert gas from an upper surface of the silicon film down to a predetermined depth.

2. The manufacturing method of the semiconductor device according to claim 1, wherein
the inert gas is nitrogen, helium, neon, argon, krypton, xenon, or radon.

3. The manufacturing method of the semiconductor device according to claim 1, wherein
a condition of the ion implantation of the inert gas is energy of 1 to 100 keV and dose of 5×10¹⁴ cm⁻² or more.

4. The manufacturing method of the semiconductor device according to claim 1, wherein
the inert gas which is ion-implanted in the step (h) does not reach an interface between the substrate and the gate insulating film.

5. The manufacturing method of the semiconductor device according to claim 1, wherein
an upper portion of the silicon film is converted to be an amorphous structure by the ion implantation of the inert gas.

6. The manufacturing method of the semiconductor device according to claim 1, wherein
the first conductivity type is n type.

7. The manufacturing method of the semiconductor device according to claim 1, wherein
a sheet resistance of the gate electrode is about 10 Ω/sq.

8. The manufacturing method of the semiconductor device according to claim 1, wherein
a gate length of the gate electrode is shorter than 0.1 μm.

9. A manufacturing method of a semiconductor device forming a field-effect transistor of a first conductivity type in a first region and forming a field-effect transistor of a second conductivity type different from the first conductivity type in a second region different from the first region, comprising the following steps:
(a) a step for forming a gate insulating film on a surface of a substrate in the first region and the second region;
(b) a step for forming a silicon film on the gate insulating film;
(c) a step for ion-implanting an impurity of the second conductivity type into the silicon film in the second region;
(d) a step for ion-implanting an impurity of the first conductivity type into the silicon film in the first region;
(e) a step for forming a gate electrode in each of the first region and the second region by processing the silicon film after the step (d);
(f) a step for forming a sidewall formed of an insulating film on a side wall of the gate electrode in each of the first region and the second region;
(g) a step for ion-implanting the impurity of the first conductivity type into the substrate in the first region with using the gate electrode and the sidewall as a mask;
(h) a step for ion-implanting the impurity of the second conductivity type into the substrate in the second region with using the gate electrode and the sidewall as a mask; and
(i) a step for forming a silicide layer on an upper portion of the silicon film configuring the gate electrode in each of the first region and the second region, and
further comprising the following step between the step (c) and the step (d) or between the step (d) and the step (e):
(j) a step for ion-implanting a first inert gas from an upper surface of the silicon film down to a predetermined depth in the first region.

10. The manufacturing method of the semiconductor device according to claim 9, wherein
the first inert gas is nitrogen, helium, neon, argon, krypton, xenon, or radon.

11. The manufacturing method of the semiconductor device according to claim 9, wherein
a condition of the ion implantation of the first inert gas is energy of 1 to 100 keV and dose of 5×10¹⁴ cm⁻² or more.

12. The manufacturing method of the semiconductor device according to claim 9, wherein
the first inert gas which is ion-implanted in the step (j) does not reach an interface between the substrate and the gate insulating film in the first region.

13. The manufacturing method of the semiconductor device according to claim 9, wherein
an upper portion of the silicon film in the first region is converted to be an amorphous structure by the ion implantation of the first inert gas.

14. The manufacturing method of the semiconductor device according to claim 9, wherein
the first conductivity type is n type, and the second conductivity type is p type.

15. The manufacturing method of the semiconductor device according to claim 9, wherein
a sheet resistance of the gate electrode in the first region is about 10 Ω/sq.

16. The manufacturing method of the semiconductor device according to claim 9, wherein
a gate length of the gate electrode in the first region is shorter than 0.1 μm.

17. The manufacturing method of the semiconductor device according to claim 9 further comprising the following step between the step (b) and the step (c) or between the step (c) and the step (d):
(k) a step for ion-implanting a second inert gas from an upper surface of the silicon film down to a predetermined depth in the second region.

18. The manufacturing method of the semiconductor device according to claim 17, wherein
the second inert gas is nitrogen, helium, neon, argon, krypton, xenon, or radon.

19. The manufacturing method of the semiconductor device according to claim 17, wherein
a condition of the ion implantation of the second inert gas is energy of 1 to 100 keV and dose of 5×10¹⁴ cm⁻² or more.

20. The manufacturing method of the semiconductor device according to claim 17, wherein
the second inert gas which is ion-implanted in the step (k) does not reach an interface between the substrate and the gate insulating film in the second region.

21. The manufacturing method of the semiconductor device according to claim 17, wherein
an upper portion of the silicon film in the second region is converted to be an amorphous structure by the ion implantation of the second inert gas.

22. The manufacturing method of the semiconductor device according to claim 17, wherein
a dose and a profile of the first inert gas ion-implanted into the silicon film in the first region are different from a dose and a profile of the second inert gas ion-implanted into the silicon film in the second region.

23. A semiconductor device comprising:
a gate insulating film formed on a surface of a substrate in a first region and a second region;
a first gate electrode formed of a silicon film of a first conductivity type and a silicide layer formed on the gate insulating film in the first region;
a second gate electrode formed of a silicon film of a second conductivity type different from the first conductivity type and a silicide layer formed on the gate insulating film in the second region; and
a sidewall formed on side walls of the first gate electrode and the second gate electrode, wherein
the silicon film configuring the first gate electrode contains a first inert gas.

24. The semiconductor device according to claim 23, wherein
the first inert gas is nitrogen, helium, neon, argon, krypton, xenon, or radon.

25. The semiconductor device according to claim 23, wherein
the first conductivity type is n type, and the second conductivity type is p type.

26. The semiconductor device according to claim 23, wherein
the silicon film configuring the first gate electrode has a polycrystalline structure.

27. The semiconductor device according to claim 23, wherein
a sheet resistance of the first gate electrode is 10 Ω/sq. or less.

28. The semiconductor device according to claim 23, wherein
a gate length of the first gate electrode is shorter than 0.1 μm.

29. The semiconductor device according to claim 23, wherein
the silicon film configuring the second gate electrode contains a second inert gas.

30. The semiconductor device according to claim 29, wherein
the second inert gas is nitrogen, helium, neon, argon, krypton, xenon, or radon.

31. The semiconductor device according to claim 29, wherein
a concentration and a profile of the first inert gas contained in the silicon film configuring the first gate electrode are different from a concentration and a profile of the second inert gas contained in the silicon film configuring the second gate electrode.

32. The semiconductor device according to claim 29, wherein
the silicon film configuring the second gate electrode has a polycrystalline structure.
